(19) United States
(12) Patent Application Publication
(10) Pub. No.: US 2010/0059840 A1
(43) Pub. Date: Mar. 11, 2010

(54) CMOS IMAGE SENSOR AND METHOD FOR MANUFACTURING THE SAME

(76) Inventor: Young-Je Yun, Yongin-si (KR)

Correspondence Address: SHERR & VAUGHN, PLLC, 620 HERNDON PARKWAY, SUITE 320, HERNDON, VA, 20170, US

(21) Appl. No.: 12/548,693

(22) Filed: Aug. 27, 2009

(30) Foreign Application Priority Data
Sep. 5, 2008 (KR) 10-2008-0087611

(51) Int. Cl. H01L 31/0232

(52) U.S. Cl. 257/432; 438/70; 438/72; 257/E31.127

(57) ABSTRACT

A Complementary Metal Oxide Semiconductor (CMOS) image sensor and a method for manufacturing the same are disclosed. The CMOS image sensor includes a photodiode formed in a semiconductor substrate, an inter dielectric layer formed over the semiconductor substrate in which the photodiode is formed, at least one metal line layer formed in the inter dielectric layer, an anti-reflection layer formed over the metal line layer in the inter dielectric layer, a color filter layer formed over the inter dielectric layer, and a micro-lens formed over the color filter layer.

The present application claims priority under 35 U.S.C. 119 to Korean Patent Application No. 10-2008-0087611 (filed on Sep. 5, 2009), which is hereby incorporated by reference in its entirety.

### BACKGROUND

Image sensors are semiconductor devices which convert optical images into electric signals. Examples of image sensors include a Charge Coupled Device (CCD) image sensor and a Complementary Metal Oxide Semiconductor (CMOS) image sensor. These image sensors include a light receiving region, which includes photodiodes used to detect light, and a logic region which processes the detected light into electric signals so as to obtain optical data. Efforts to enhance optical sensitivity have been in progress.

In a CMOS image sensor, crosstalk, which denotes interference of optical signals between adjacent pixels, may occur due to a reduction in the size of pixels. The crosstalk has an effect on the quality of the CMOS image sensor.

FIG. 1 is a view illustrating a configuration of a related CMOS image sensor. Referring to FIG. 1, the CMOS image sensor includes a semiconductor substrate 110, a device isolating layer 115, photodiodes 120 and 125, an inter dielectric layer 130, a metal line layer 140, a passivation layer 150, color filter layers 155, a planarization layer 160, and micro-lenses 165.

FIG. 2 is an explanatory view of crosstalk between the adjacent photodiodes shown in FIG. 1. Referring to FIG. 2, the metal line layer 140 may include of a plurality of metal line layers, for example, a first metal line layer 210, a second metal line layer 220, and a third metal line layer 230. In this CMOS image sensor, a part of optical signals transmitted to the first photodiode 120 may be diffusively reflected by the metal line layer 140 to thereby be transmitted to the adjacent second photodiode 125. For example, in optical signals transmitted to the first photodiode 120, lateral incident light 250 is reflected from the top of a first metal line 212 in the second metal line layer 220. Then, the reflected lateral incident light is re-reflected from the bottom of the third metal line layer 230. The re-reflected lateral incident light is repeatedly reflected from the top of a second metal line 214 of the second metal line layer 220, and again from the bottom of the third metal line layer 230, thereby being transmitted to the adjacent second photodiode 125. This may problematically cause crosstalk between the adjacent photodiodes.

### SUMMARY

Embodiments relate to semiconductor devices, and more particularly, to a Complementary Metal Oxide Semiconductor (CMOS) image sensor and a method for manufacturing the same. Embodiments relate to a Complementary Metal Oxide Semiconductor (CMOS) image sensor and a method for manufacturing the same, which may restrict occurrence of crosstalk due to diffuse reflection of lateral incident light with respect to metal lines.

Embodiments relate to a Complementary Metal Oxide Semiconductor (CMOS) image sensor which may include a photodiode formed in a semiconductor substrate, an inter dielectric layer formed over the semiconductor substrate in which the photodiode is formed, at least one metal line layer formed in the inter dielectric layer, an anti-reflection layer formed over the metal line layer in the inter dielectric layer, a color filter layer formed over the inter dielectric layer, and a micro-lens formed over the color filter layer.

Embodiments relate to a method for manufacturing a CMOS image sensor which may include forming a photodiode in a semiconductor substrate, forming a first dielectric layer over the semiconductor substrate in which the photodiode is formed, forming a first metal line layer over the first dielectric layer, the first metal line layer including a first metal line and a first anti-reflection layer stacked over the first metal line, forming a second dielectric layer over the first metal line layer, forming a color filter layer over the second dielectric layer to correspond to the photodiode, and forming a micro-lens to correspond to the color filter layer.

### DRAWINGS

FIG. 1 is a view illustrating a configuration of a related CMOS image sensor;

FIG. 2 is an explanatory view of crosstalk between adjacent photodiodes shown in FIG. 1.

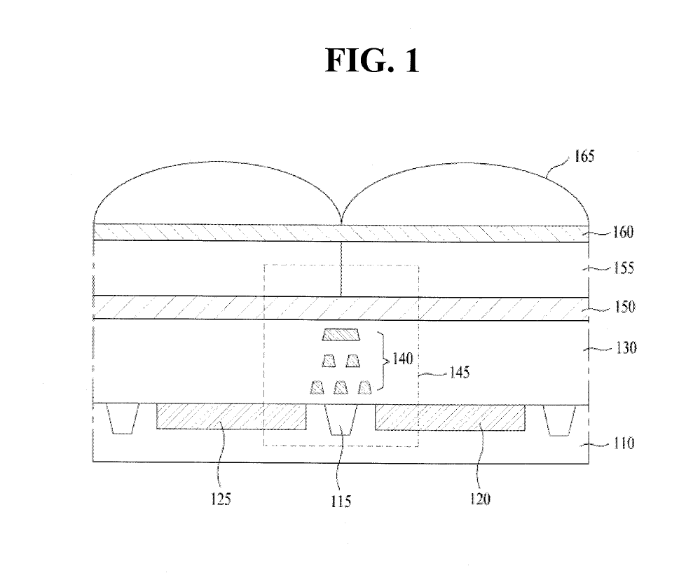

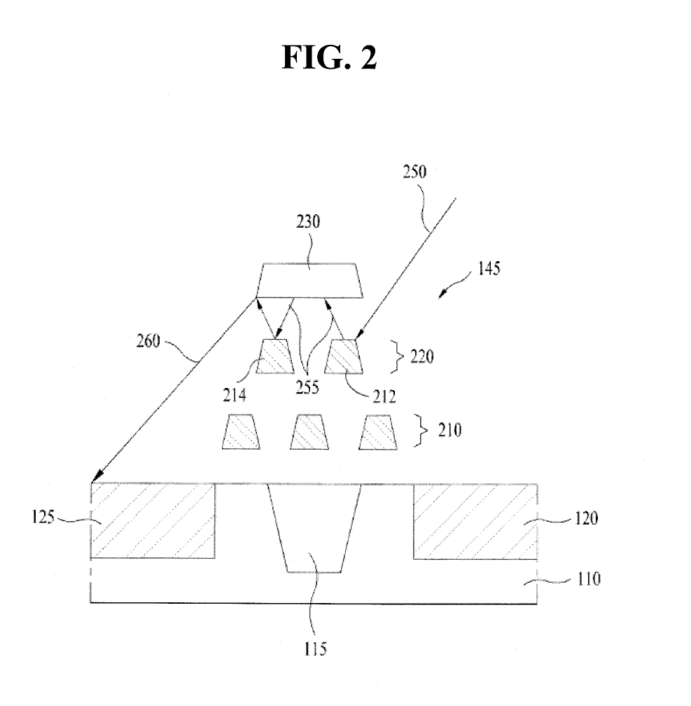

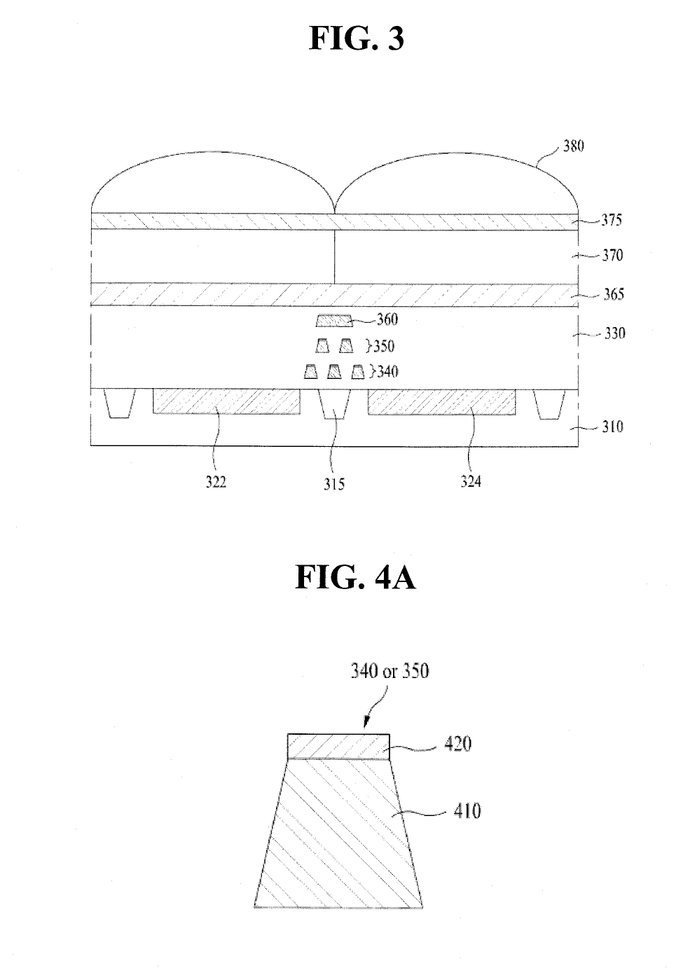

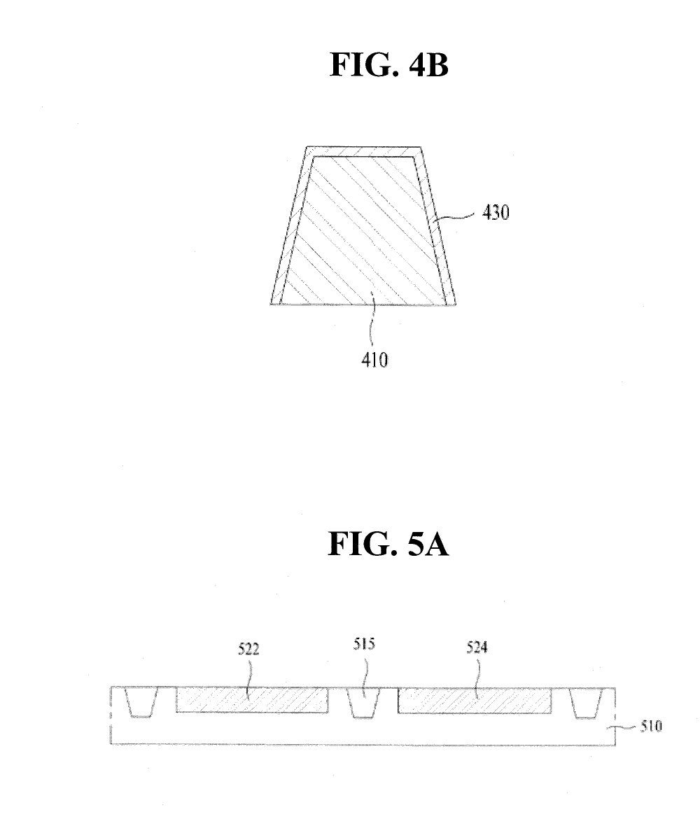

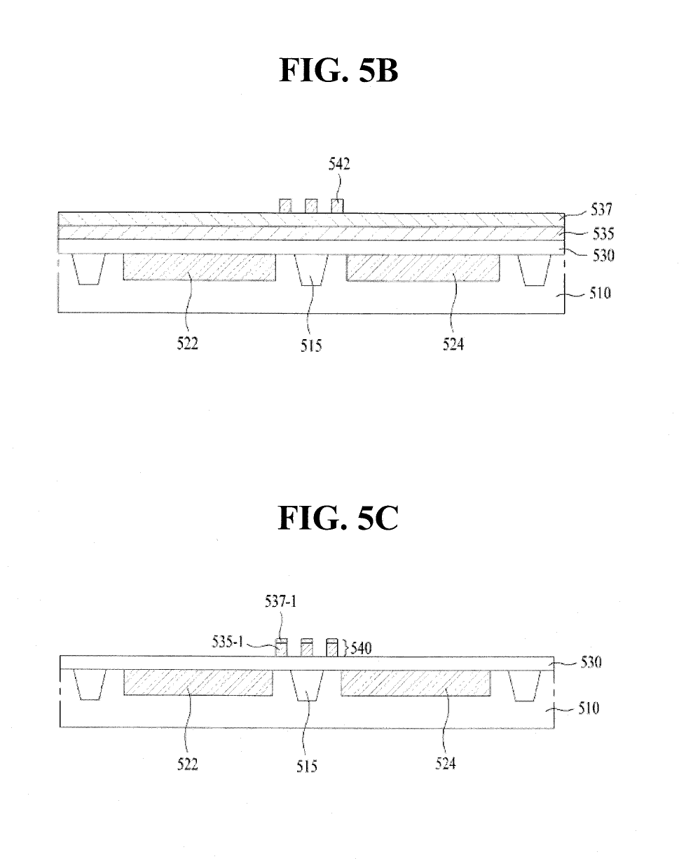

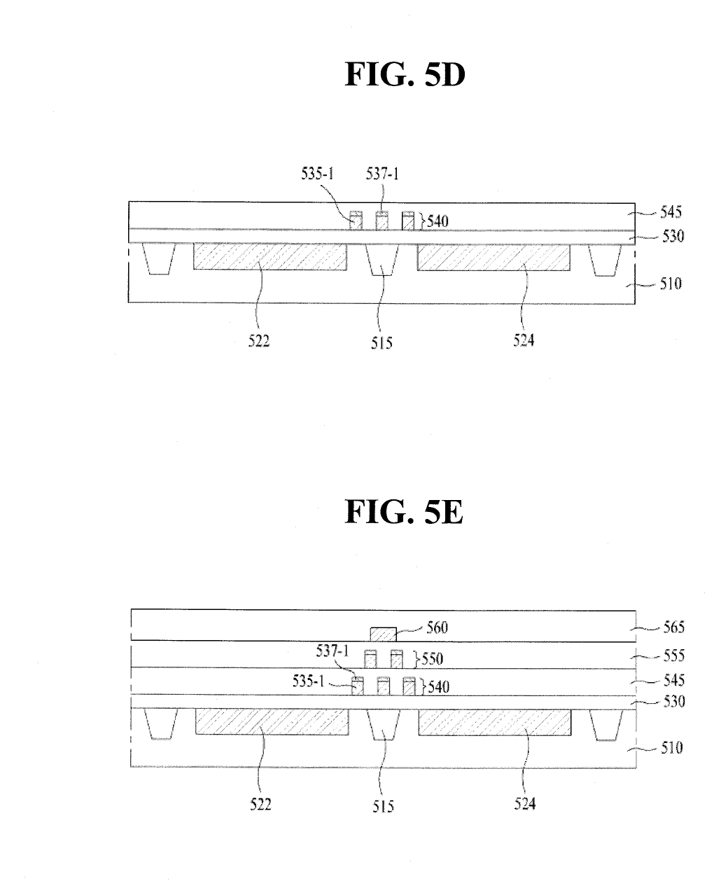

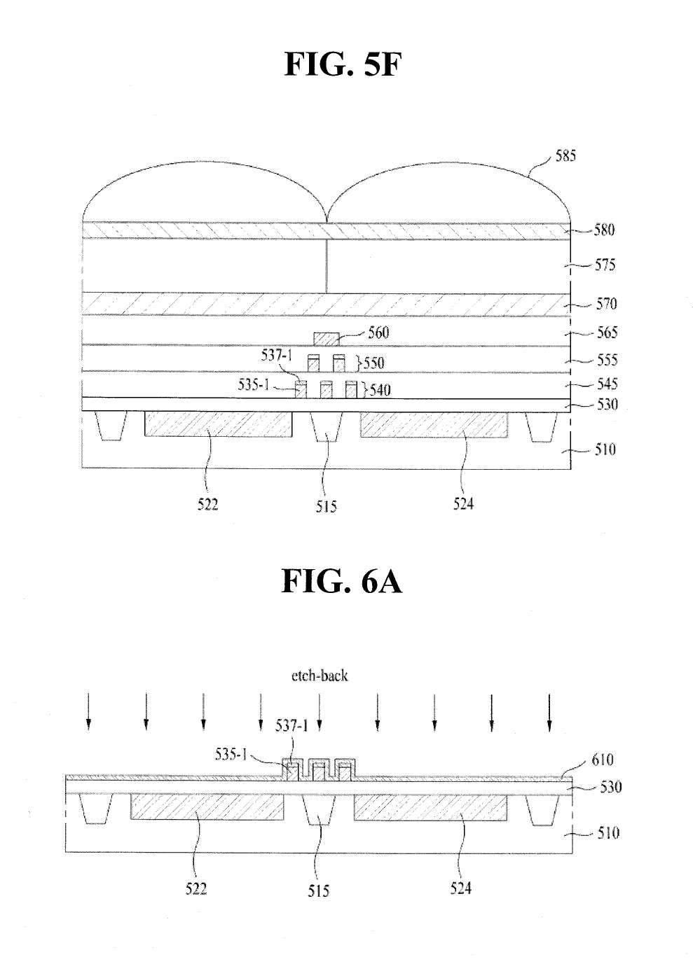

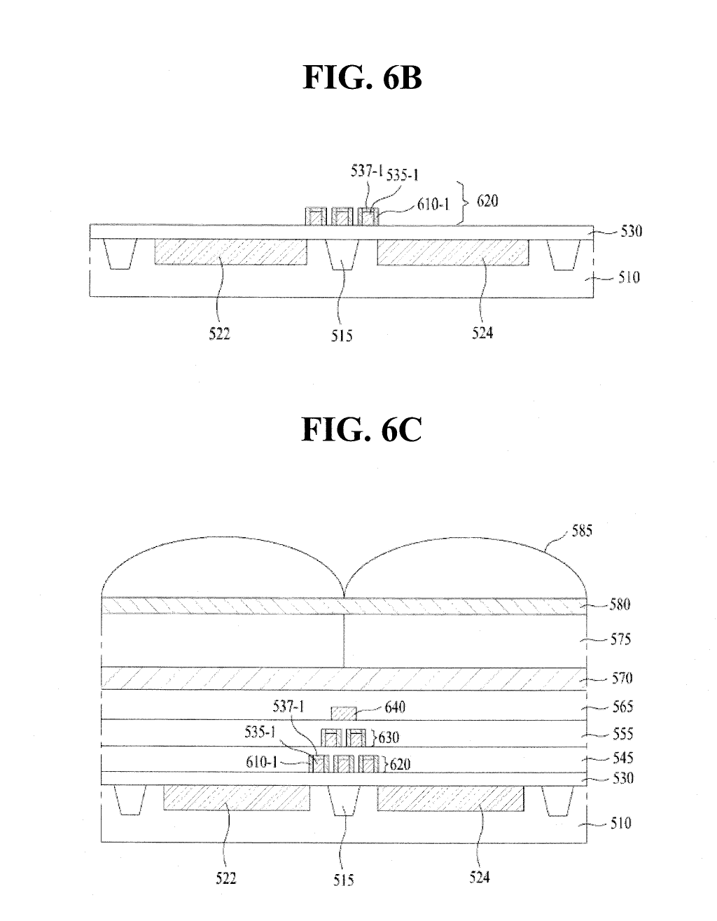

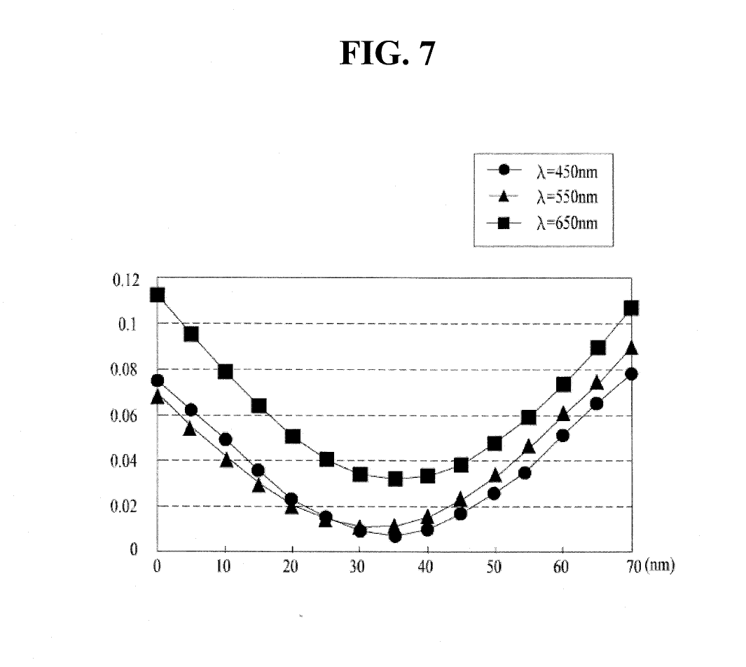

Example FIG. 3 is a view illustrating a CMOS image sensor according to embodiments.

Example FIGS. 4a and 4b are views illustrating different embodiments of a metal line layer shown in example FIG. 3.

Example FIGS. 5a to 5f are process sectional views illustrating a method for manufacturing a CMOS image sensor according to embodiments.

Example FIGS. 6a to 6c are process sectional views illustrating a method for manufacturing a CMOS image sensor according to embodiments.

Example FIG. 7 is a graph illustrating reflectivity based on configurations of metal line layers shown in example FIGS. 5f and 6c.

### DESCRIPTION

Example FIG. 3 is a view illustrating a CMOS image sensor according to embodiments, and example FIGS. 4a and 4b are views illustrating embodiments of a metal line layer shown in example FIG. 3. Referring to example FIGS. 3, 4a, and 4b, the CMOS image sensor may include a device isolating layer 315 formed in a semiconductor substrate 310. Photodiodes 322 and 324 may be formed in the semiconductor substrate 310. An inter dielectric layer 330 may be formed over the semiconductor substrate 310 in which the photodiodes 322 and 324 are formed, and at least one metal line layer 340, 350 and 360 may be formed in the inter dielectric layer 330. An anti-reflection layer 420 may be formed over the at least one metal line layer. A passivation layer 365 may be formed over the inter dielectric layer 330. The CMOS image sensor may include color filter layers 370 formed over the passivation layer 365, a planarization layer 375 formed over the color filter layers 370, and micro-lenses 380 formed over the planarization layer 375.

The at least one metal line layer 340, 350 and 360 may include a first metal line layer 340, a second metal line layer 350, and a third metal line layer 360, which are sequentially stacked, one above another. The first metal line layer 340 and second metal line layer 350 may respectively include a metal line 410 and the anti-reflection layer 420 or 430.

A part of optical signals transmitted to the first photodiode 324, i.e. lateral incident light may be diffusively reflected by the at least one metal line layer 340, 350 and 360 to thereby be transmitted to the adjacent second photodiode 322, causing crosstalk between the adjacent photodiodes 322 and 324. To solve this problem, the at least one metal line layer 340, 350 and 360 may include, over an upper surface thereof, an anti-reflection layer 420 or 430. The anti-reflection layer 420 according to embodiments may be formed to cover the upper surface of the metal line 410. The anti-reflection layer 430 according to embodiments may be formed to cover both the upper surface and sidewall of the metal line 410.

The anti-reflection layers 420 and 430 serve to prevent a part of optical signals transmitted to the first photodiode 324, i.e. lateral incident light, from being diffusively reflected by the upper surface or sidewall of the metal line layer. These anti-reflection layers 420 and 430 may be made of silicon nitride (e.g., SiN).

Example FIGS. 5a to 5f are process sectional views illustrating a method for manufacturing a CMOS image sensor according to embodiments. First, as shown in example FIG. 5a, a device isolating layer 515 may be formed in a semiconductor substrate 510 by a Shallow Trench Isolation (STI) method or Recessed-Local Oxidation of Silicon (R-LOCOS) method. The device isolating layer 515 defines an active area and a device isolating area. Subsequently, dopant ions are implanted into the active area of the semiconductor substrate, to form photodiodes 522 and 524. In this case, the device isolating layer 515 may be made of Undoped Silicate Glass (USG), and may be formed after the photodiodes 522 and 524 are first formed in the semiconductor substrate 510.

Next, as shown in example FIG. 5b, a first dielectric layer 530 may be formed over the semiconductor substrate 510 in which the photodiodes 522 and 524 are formed. In this case, the first dielectric layer 530 may be an oxide layer. Subsequently, a first metal layer 535 may be formed over the first dielectric layer 530 and in turn, an anti-reflection material 537 may be applied to the first metal layer 535. In this case, the anti-reflection material 537 may be silicon nitride (SiN), and the first metal layer 535 may be aluminum. The applied anti-reflection material 537 may be subjected to a photolithography process, to form a first photoresist pattern 542.

Next, as shown in example FIG. 5c, the anti-reflection material 537 and first metal layer 535 may be etched using the first photoresist pattern 542 as an etching mask, to form a first metal line layer 540. The first metal line layer 540 may include a first metal line 535-1 and an anti-reflection layer 537-1 stacked over the first metal line 535-1. Thereafter, the first photoresist pattern may be removed.

As shown in example FIG. 5d, a second dielectric layer 545 may be formed over the first dielectric layer 530 over which the first metal line layer 540 is formed. In this case, the second dielectric layer 545 may be an oxide layer.

Next, as shown in example FIG. 5e, a second metal line layer 550 may be formed over the second dielectric layer 545. The second metal line layer 550 may be formed in the same manner as the above-described first metal line layer 540. That is, the second metal line layer 550 may include a second metal line and an anti-reflection layer. The second metal line layer 550 may be patterned differently than the first metal line layer 540.

A third dielectric layer 555 may be formed over the second dielectric layer 545 over which the second metal line layer 550 is formed. In this case, the third dielectric layer 555 may be an oxide layer. Next, a third metal line layer 560 may be formed over the third dielectric layer 555. The third metal line layer 560 may be an uppermost metal line layer and thus, may have no anti-reflection layer formed over any metal lines. This is because no metal line may be present above the third metal line layer 560 and therefore, no re-reflection of optical signals reflected from the third metal line layer 560 will occur. A fourth dielectric layer 565 may be formed over the third dielectric layer 555 over which the third metal line layer 560 is formed.

The above-described first to third metal line layers 540, 550 and 560 constitute a multiple layer metal wiring of the CMOS image sensor, and the above-described first to fourth dielectric layers 530, 545, 555 and 565 constitute an inter dielectric layer of the CMOS image sensor. Therefore, the multiple layer metal line may be formed within the inter dielectric layer.

Next, as shown in example FIG. 5f, a passivation layer 570 may be formed over the fourth dielectric layer 565. The passivation layer serves to protect semiconductor devices of the CMOS image sensor from moisture and scratches. Then, color filter layers 575 may be formed over the passivation layer 570, to correspond to the photodiodes 522 and 524. A planarization layer 580 may be formed over the color filter layers 575, e.g., to achieve planarization for adjustment of a focal distance and formation of a lens layer. Micro-lenses 585 may be formed over the color filter layer 575, to correspond to the color filter layers 575.

Example FIGS. 6a to 6c are process sectional views illustrating a method for manufacturing a CMOS image sensor according to embodiments. First, as shown in example FIG. 6a, a metal line layer may be formed over the first dielectric layer 530 that is formed over the semiconductor substrate 510. The metal line layer may include the first metal line 535-1 and anti-reflection layer 537-1 (hereinafter, referred to as a “first anti-reflection layer”) stacked over the first metal line 535-1. A description related to the formation of the metal line layer is similar to the above description of example FIGS. 5a to 5c and thus, will be omitted herein to avoid repetition.

A second anti-reflection layer 610 may be formed over the entire surface of the first dielectric layer 530, over which the metal line layer, including the first metal line 535-1 and first anti-reflection layer 537-1 is formed. In this case, the second anti-reflection layer 610 may be thinly deposited over a surface of the first dielectric layer 530, a sidewall of the first metal line 535-1, and an upper surface of the first anti-reflection layer 537-1.

Subsequently, the entire surface of the semiconductor substrate 510, over which the second anti-reflection layer 610 is deposited, may be subjected to an etch-back process. With implementation of the etch-back process, a part of the second anti-reflection layer 610, deposited over the surface of the first dielectric layer 530 and the upper surface of the first anti-reflection layer 537-1, is etched away. The second anti-reflection layer 610 deposited over the sidewall of the first metal line 535-1 remains. That is, the first anti-reflection layer 537-1 stays over the first metal line 535-1 and the second anti-reflection layer 610-1 stays over the sidewall of the first metal line 535-1. Thereby, both the upper surface and sidewall of the first metal line 535-1 are covered with the residual first anti-reflection layer 537-1 and second anti-reflection layer 610-1.

Accordingly, the metal line layer 540 shown in example FIG. 5c differs from the metal line layer 620 shown in example FIG. 6b, in the sense that the anti-reflection layer 537-1 of the metal line layer 540 is formed only over the upper surface of the first metal line 535-1, but the anti-reflection layers 537-1 and 610-1 of the metal line layer 620 are formed over both the upper surface and sidewall of the first metal line 535-1. Next, as shown in example FIG. 6c, the second dielectric layer 545 may be formed over the first dielectric layer over which the first metal line layer 620 is formed.

The subsequent manufacturing processes of the CMOS image sensor are similar to the description of example FIGS. 5d to 5f, except for the formation of the metal line layer as described above, and thus a description thereof will be omitted.

Example FIG. 7 is a graph illustrating reflectivity based on configurations of the metal line layers shown in example FIGS. 5f and 6c. In the graph shown in example FIG. 7, the ordinate represents reflectivity, and the abscissa represents a thickness of an anti-reflection layer. Here, the reflectivity also depends on a wavelength λ.

Referring to example FIG. 7, it can be appreciated that providing the anti-reflection layer with respect to visible wavelength light reduces reflectivity at the top of a metal line by 5˜10%.

Although example FIGS. 5a to 5f and example FIGS. 6a to 6c illustrate the single silicon nitride layer stacked over the metal line, embodiments are not limited thereto, and at least two oxide layers and nitride layers may be stacked over the metal line.

Since lateral incident light transmitted to any one photodiode has an incidence angle of about 0˜20 degrees, due to the interface between a micro-lens and air, crosstalk between adjacent photodiodes is greatly affected not by an optical path penetrating between metal lines, but by a path along which light is diffusively reflected from the upper surface of the metal line to thereby be transmitted to the adjacent photodiode. Accordingly, there exists a great need to restrict crosstalk due to diffuse reflection of lateral incident light.

To prevent crosstalk due to the diffuse reflection of lateral incident light with respect to the metal line, in embodiments, it is proposed that the anti-reflection layer is formed over the upper surface of the metal line, or is formed over both the upper surface and sidewall of the metal line, so as to prevent the diffuse reflection of lateral incident light from the upper surface of the metal line and consequently, to restrict crosstalk between the adjacent photodiodes.

As apparent from the above description, in a CMOS image sensor and a method for manufacturing the same according to embodiments, providing an anti-reflection layer over an upper surface of a metal line or over both the upper surface and sidewall of the metal line may prevent occurrence of diffuse reflection of lateral incident light, thereby restricting crosstalk between adjacent photodiodes.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. An apparatus comprising:
a photodiode formed in a semiconductor substrate;
an inter dielectric layer formed over the semiconductor substrate in which the photodiode is formed;
at least one metal line layer formed in the inter dielectric layer; and
an anti-reflection layer formed over the metal line layer in the inter dielectric layer.

2. The apparatus of claim 1, wherein the at least one metal line layer includes two or more metal line layers stacked one above another within the inter dielectric layer.

3. The apparatus of claim 2, wherein the anti-reflection layer covers only an upper surface of each of the metal line layers.

4. The apparatus of claim 2, wherein the anti-reflection layer covers an upper surface and sidewall of each of the metal line layers.

5. The apparatus of claim 1, wherein the anti-reflection layer is a silicon nitride layer.

6. The apparatus of claim 1, including a color filter layer formed over the inter dielectric layer.

7. The apparatus of claim 6, including a micro-lens formed over the color filter layer.

8. The apparatus of claim 6, including a passivation layer formed between the inter dielectric layer and the color filter layer.

9. The apparatus of claim 1, wherein the inter dielectric layer includes a plurality of layers of oxide.

10. A method comprising:
forming a photodiode in a semiconductor substrate;
forming a first dielectric layer over the semiconductor substrate in which the photodiode is formed;
forming a first metal line layer over the first dielectric layer, the first metal line layer including a first metal line and a first anti-reflection layer stacked over the first metal line; and
forming a second dielectric layer over the first metal line layer.

11. The method of claim 10, wherein the formation of the first metal line layer includes:
forming a first metal layer over the first dielectric layer;
applying an anti-reflection material over the first metal layer;
forming a first photoresist pattern over the anti-reflection material;
etching the anti-reflection material and first metal layer using the first photoresist pattern, so as to form the first metal line layer in which the first anti-reflection layer is stacked over the first metal line; and
removing the first photoresist pattern.

12. The method of claim 11, wherein the formation of the first metal line layer includes:
forming a second anti-reflection layer over the entire surface of the first dielectric layer over which the first metal line layer, including the first anti-reflection layer stacked over the first metal line, is formed; and
performing an etch-back process over the entire surface of the semiconductor substrate over which the second anti-reflection layer is deposited, leaving the first anti-reflection layer over an upper surface of the first metal line and leaving the second anti-reflection layer over a sidewall of the first metal line.

13. The method of claim 10, including:
forming a second metal line layer over the second dielectric layer, the second metal line layer including a second metal line and an additional anti-reflection layer stacked over the second metal line.

14. The method of claim 13, including:
forming a third dielectric layer over the second dielectric layer over which the second metal line layer is formed.

15. The method of claim 11, wherein the anti-reflection material is silicon nitride.

16. The method of claim 10, wherein the first metal layer is made of aluminum.

17. The method of claim 10, including forming a passivation layer over the second dielectric layer.

18. The method of claim 17, including forming a color filter layer over the passivation layer to correspond to the photodiode.

19. The method of claim 18, including forming a planarization layer over the color filter layer.

20. The method of claim 19, including forming a micro-lens to correspond to the color filter layer.
